(19) United States
(12) Patent Application Publication
(10) Pub. No.: US 2025/0301701 A1
(43) Pub. Date: Sep. 25, 2025

(54) INTEGRATED CIRCUIT AND SEMICONDUCTOR CHIP

(71) Applicant: Taiwan Semiconductor Manufacturing Company, Ltd., Hsinchu (TW)

(72) Inventors: Ta-Chun LIN, Hsinchu (TW); Hsin-Huang Lin, Taichung City (TW); Yi-Ren Chen, Taoyuan City (TW); Chih-Hao Chang, Hsin-Chu (TW); Jhon Jhy Liaw, Hsinchu County (TW)

(73) Assignee: Taiwan Semiconductor Manufacturing Company, Ltd., Hsinchu (TW)

(21) Appl. No.: 18/611,707

(22) Filed: Mar. 21, 2024

(51) Int. Cl. H01L 29/417; H01L 23/522; H01L 23/528; H01L 27/092; H01L 29/423; H01L 29/775; H01L 29/786

(52) U.S. Cl. CPC H10D 30/6729; H01L 23/5226; H01L 23/5286; H10D 84/85; H10D 30/43; H10D 30/6735; H10D 30/6757

(57) ABSTRACT

An integrated circuit and a semiconductor chip are provided. The integrated circuit includes: an active region, defined on a substrate by a surrounding isolation structure; a gate structure, intersecting and covering the active region; a first source/drain contact pattern, intersecting the active region at a first side of the gate structure; and a second source/drain contact pattern, intersecting the active region at a second side of the gate structure, and having a first section crossing the active region and a second section extending away from the first section and overlapped with a power rail. The first section has a first width shorter than a second width of the second section.

### BACKGROUND

Along with quick development of semiconductor industry, integrated circuits have become more complicated in functionality and faster in operation speed, yet more compact in size. The miniaturization of integrated circuits includes reducing spacing between adjacent circuit components, which inevitably increases risk of forming leakage paths between the circuit components. In order to maintain sufficient spacing in between, the circuit components highly susceptible of leakage may be formed with smaller width. However, for those conductive features, reducing pattern width may increase voltage drop along length direction, and also increase contact resistance with via(s) standing thereon.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic plan view illustrating a portion of an integrated circuit, according to some embodiments of the present disclosure.

FIG. 2A is a schematic cross-sectional view along an A-A′ line shown in FIG. 1.

FIG. 2B is a schematic cross-sectional view along a B-B′ line shown in FIG. 1.

FIG. 2C is a schematic cross-sectional view along a C-C′ line shown in FIG. 1.

FIG. 3 is a schematic plan view illustrating an originally designed pattern and a manufactured pattern of one of the source-side contact patterns, according to some embodiments of the present disclosure.

FIG. 4 is a schematic plan view illustrating one of the source-side contact patterns, according to some embodiments of the present disclosure.

FIG. 5A and FIG. 5B are schematic plan views respectively illustrating one of the drain-side contact patterns, according to some embodiments of the present disclosure.

FIG. 6 is a schematic plan view illustrating a semiconductor chip according to some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides a solution for integrated circuit scaling. While preventing leakage between middle-end-of-line (MEOL) contact patterns and adjacent gate structures, contact resistance between the contact patterns and overlying power rails can be maintained or even reduced.

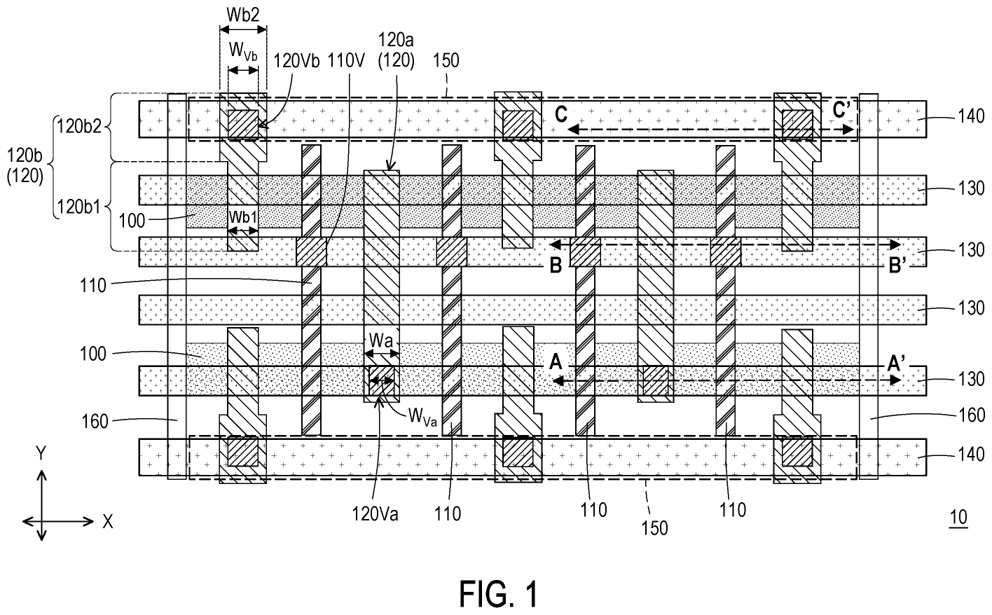

FIG. 1 is a schematic plan view illustrating a portion of an integrated circuit 10, according to some embodiments of the present disclosure.

In the integrated circuit 10, active devices and/or passive devices are interconnected to perform various functions. Layout and structures of the integrated circuit 10 will be described in detail, to demonstrate how the advantageous effects can be achieved. On the other hand, the interconnection of the active devices and/or passive devices in the integrated circuit 10 as well as the designed functions of the integrated circuit 10 may not be specified, as the present disclosure is not limited thereto.

The integrated circuit 10 may include columns and rows of cells, and one of the cells is shown in FIG. 1. Active regions 100 defined (surrounded) by an isolation structure (not shown) may extend along a first direction X, while gate structures 110 intersecting and covering the active regions 100 may extend along a second direction Y. Field effect transistors (FETs) are respectively defined in a vicinity of an intersection of one of the active regions 100 and one of the gate structures 110. Channel regions of the FETs are provided by the active regions 100, and gate terminals of the FETs are provided by the gate structures 110. As will be further described, the active regions 100 may be cut off at opposite sides of each intersecting gate structure 110, and the resulted spacings may be filled by epitaxial structures functioned as source/drain terminals of the FETs.

As contacts to the source/drain terminals of the FETs, contact patterns 120 are disposed on top of the epitaxial structures, and are positioned at opposite sides of each gate structure 110. In addition, the contact patterns 120 may extend along the second direction Y, as similar to the gate structures 110. As a result, the gate structures 110 and the contact patterns 120 may extend across the active regions 100 along the same direction (i.e., the direction Y), and the gate structures 110 are respectively located between the contact patterns 120 at opposite sides.

Depending on circuit design, some of the gate structures 110 may extend across multiple ones of the active regions 100, and are respectively shared by the FETs formed along. Similarly, while others of the contact patterns 120 respectively extend across a single one of the active regions 100, some of the contact patterns 120 may extend across multiple ones of the active regions 100, and are respectively shared by the FETs formed along. In addition, the contact patterns 120 solely extending between two gate structures 110 may be respectively functioned as a common source/drain terminal of the FETs at opposite sides.

Signal lines 130 and power rails 140 may run over the FETs, and extend across the integrated circuit 10. The gate structures 110 may be respectively connected to one of the signal lines 130. On the other hand, a first group of the contact patterns 120 (also referred to as contact patterns 120a) as contacts to the drain terminals of the FETs may be respectively connected to one of the signal lines 130, whereas a second group of the contact patterns 120 (also referred to as contact patterns 120b) as the source terminals of the FETs may be respectively connected to one of the power rails 140. Conductive vias 110V may be used for establishing electrical connection between the gate structures 110 and the corresponding signal lines 130. In addition, conductive vias 120Va may be used for establishing electrical connection between the contact patterns 120a and the corresponding signal lines 130, and conductive vias 120Vb may be used for establishing electrical connection between the contact patterns 120b and the power rails 140.

As each gate structure 110 extends between a pair of the contact patterns 120, the contact patterns 120 are laterally adjacent to the gate structures 110. In case of aggressive scaling, the contact patterns 120 would be very close to the gate structures 110, and undesired leakage between the contact patterns 120 and the gate structures 110 may be accidentally formed. To prevent such leakage, width of the contact patterns 120 is further reduced. However, for the contact patterns 120b connected to the power rails 140, the reduced size may limit contact area to the conductive vias 120Vb extending to the power rails 140. This may result in significant voltage drop along power transmission paths. According to various embodiments of the present disclosure, each of the contact patterns 120b is designed with multiple sections having different widths. A first section of each contact pattern 120b extending along adjacent gate structures 110 has a small width, whereas a second section of each contact pattern 120b in contact with the corresponding conductive via 120Vb has a large width. In this way, undesired leakage between the contact patterns 120b and the gate structures 110 can be prevent without increasing contact resistance between the contact patterns 120b and the conductive vias 120Vb. As will be further described, specific layout design of the contact patterns 120b is related to arrangement of the power rails 140 and the signal lines 130.

The signal lines 130 and the power rails 140 may be formed in a bottommost metallization layer at a front side of the substrate. Although not shown, more of the metallization layers are stacked on the bottommost metallization layer. According to some embodiments, the signal lines 130 and the power rails 140 both extend along the first direction X, as similar to the active regions 100. For one cell (or every cell), two power rails 140 may be in line with opposite cell edges extending along the first direction X, and at least four signal lines 130 in parallel with the power rails 140 are arranged between the power rails 140.

According to such arrangement, the contact patterns 120b along the second direction Y may extend across the active regions 100, to the cell edges for connecting to the power rails 140 formed along the cell edges. A first section 120b1 of each contact pattern 120b extends across the corresponding active region 100 along the gate structures 110 at opposite sides, and has a first width Wb1. In addition, a second section 120b2 of each contact pattern 120b extending from the first section 120b1 to the closest cell edge, and has a second width Wb2 greater than the first width Wb1. As described, undesired leakage between the contact patterns 120b and the gate structures 110 can be effectively prevented by designing the first section 120b1 of each contact pattern 120b with a smaller width, and contact resistance between the contact patterns 120b and the conductive vias 120Vb can be maintained or even lowered by designing the second section 120b2 of each contact pattern 120b with a greater width. In some embodiments, the second width Wb2 is greater than the first width Wb1 by about 0.5 nm to about 10 nm. If the difference between the second width Wb2 and the first width Wb1 is less than 0.5 nm, preventing the gate to source/drain leakage and reducing contact resistance from source/drain to power rail are barely achievable at the same time. On the other hand, if the difference between the second width Wb2 and the first width Wb1 is greater than 10 nm, either the first section 120b1 of the contact pattern 120b is too narrow to have sufficiently low resistance, or the second section 120b2 of the contact pattern 120b may be too close to adjacent gate structures 110, which may risk gate to source/drain leakage as well.

Since the width Wb2 of the second section 120b2 of each contact pattern 120b is greater than the width Wb1 of the first section 120b1 of each contact pattern 120b, the conductive vias 120Vb landed on the second section 120b2 of each contact pattern 120b is allowed to be formed with a greater width W_{Vb} for reducing the contact resistance between the contact patterns 120b and the power rails 140. In some embodiments, the width W_{Vb} of each conductive via 120Vb is greater than a width W_{Va} of each conductive via 120Va landed on one of the contact patterns 120a (with the fixed width Wa to be described). In these embodiments, a footprint area of each conductive via 120Vb may be greater than a footprint area of each conductive via 120Va.

As described, the first section 120_{b}1 of each contact pattern 120b extends across the corresponding active region 100. More specifically, the first section 120b1 of each contact pattern 120b lies over an epitaxial structure disposed at where the crossed active region 100 is cut off, and may overlie the isolation structure (not shown) surrounding the crossed active region 100. On the other hand, the second section 120b2 of each contact pattern 120b extending to the closest cell edge from the first section 120b1 lies on the isolation structure (not shown), and is overlapped with the corresponding conductive via 120Vb and power rail 140.

According to some embodiments, the gate structures 110 are cut off at the cell edges. In these embodiments, gate isolation structures 150 intersecting the gate structures 110 and formed of an insulating material may be disposed along the cell edges, and are overlapped with the power rails 140 also disposed along the cell edges. As will be described in greater details, the second section 120b2 of each contact pattern 120b may laterally extend through a shallow portion of the closest gate isolation structure 150, and the corresponding conductive via 120Vb extending to the overlying power rail 140 may be landed from above this gate isolation structure 150.

In some embodiments, the active regions 100 along the first direction X extend to other cell edges (e.g., the cell edges along the second direction Y), and are cut off at these cell edges. In these embodiments, channel isolation structures 160 intersecting the active regions 100 and formed of an insulating material may be disposed along the cell edges in the second direction Y. In those embodiments where the gate structures 110 are cut off by the gate isolation structures 150, the channel isolation structures 160 cutting off the active regions 100 may intersect the gate isolation structures 150.

As compared to the contact patterns 120b extending to the cell edges in the first direction X, the contact patterns 120a connected to the signal lines 130 may extend between these cell edges. More specifically, the contact patterns 120a may extend across the active regions 100 and overlap the isolation structure (not shown) laterally surrounding the active regions 100, but may not extend to the gate isolation structures 150 disposed along the cell edges in the first direction X. Further, as compared to the contact patterns 120b each having multiple sections with different widths, the contact patterns 120a may not respectively have multiple sections with different widths. In some embodiments, each of the contact patterns 120a has a fixed width Wa along its length. The width Wa of each contact pattern 120a is shorter than the width Wb2 of the second section 120b2 in each contact pattern 120b. As a result, the width W_{Va} of each conductive via 120Va landed on one of the contact patterns 120a (with the fixed width Wa) is shorter than the width W_{Vb} of each conductive via 120Vb landed on the second section 120b2 of each contact pattern 120b, and a footprint area of each conductive via 120Va may be smaller than a footprint area of each conductive via 120Vb. In some cases, the width Wa of each contact pattern 120a as a drain-side contact is greater than the width Wb1 of the first section 120b1 of each contact pattern 120b as a source-side contact, for reducing drain side resistance.

Furthermore, in some embodiments, the width Wb1 of the contact patterns 120b and the width Wa of the contact patterns 120a connected to P-type FETs are shorter than the width Wb1 of the contact patterns 120b and the width Wa of the contact patterns 120a connected to N-type FETs, respectively. In these embodiments, as will be further described, loss of strain induced on channel regions of the P-type FETs can be particularly lowered.

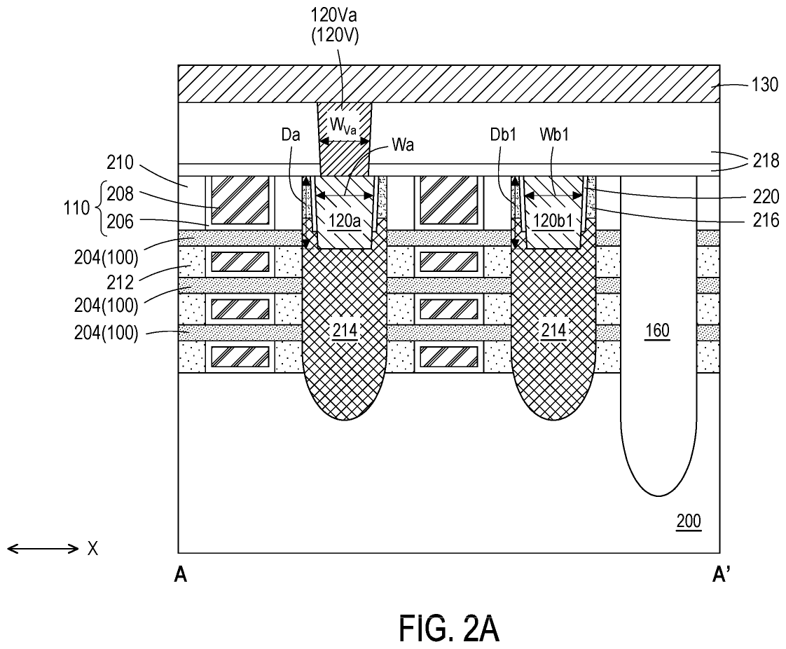

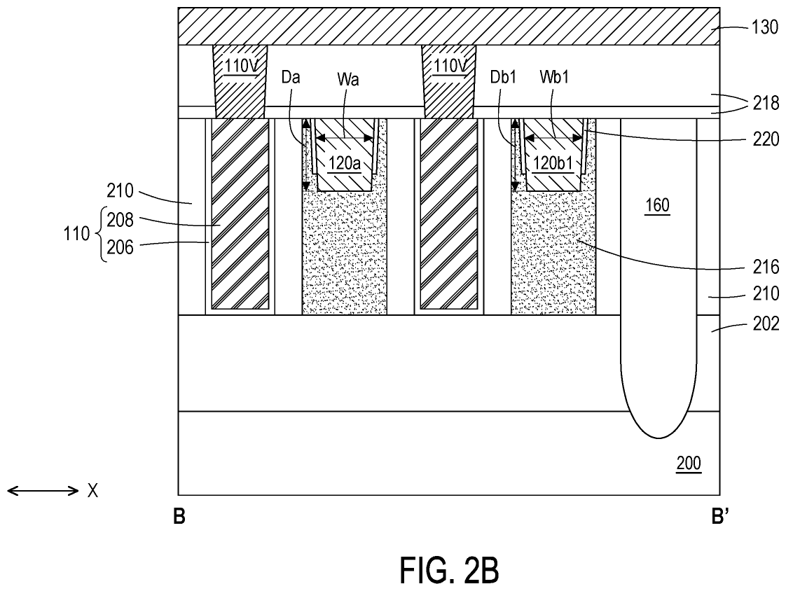

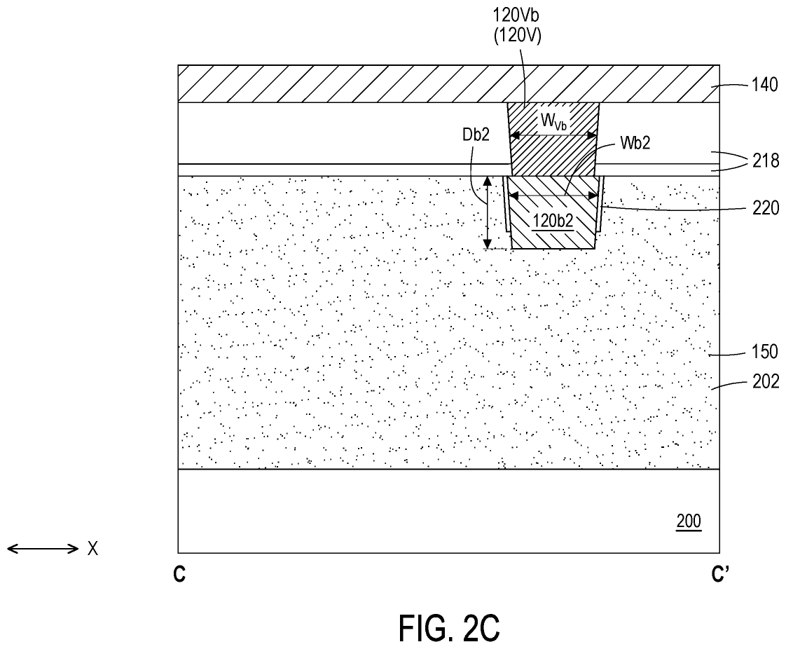

FIG. 2A is a schematic cross-sectional view along an A-A′ line shown in FIG. 1; FIG. 2B is a schematic cross-sectional view along a B-B′ line shown in FIG. 1; and FIG. 2C is a schematic cross-sectional view along a C-C′ line shown in FIG. 1.

As shown in FIG. 2A, FIG. 2B and FIG. 2C, the integrated circuit 10 is built on a semiconductor substrate 200, and the active regions 100 providing the channel regions for the FETs in the integrated circuit 10 are defined by (laterally surrounded by) an isolation structure 202 formed into the semiconductor substrate 200.

Referring to FIG. 2A, according to some embodiments, the FETs are gate-all-around (GAA) FETs, and the active regions 100 respectively include a stack of channel structures 204 formed on the semiconductor substrate 200 and laterally surrounded by the isolation structure 202 (shown in FIG. 2B and FIG. 2C). The channel structures 204 extending along the first direction X in each stack are vertically separated from one another. In addition, the channel structures 204 are formed of a semiconductor material, and may be formed as nanosheets, nanowires or the like.

In these embodiments, the gate structures 110 each including a gate dielectric layer 206 and a gate electrode 208 intersect and wrap all around the channel structures 204. More specifically, the gate dielectric layers 206 of the gate structures 110 may line along surfaces of the wrapped channel structures 204 as shown in FIG. 2A, and extend along bottom surfaces and sidewalls of the gate structures 110 as shown in FIG. 2B. The gate electrodes 208 may cover the gate dielectric layers 206, and fill up rest space of the gate structures 110. In this way, the channel structures 204 are embedded in, and laterally penetrate through the gate structures 110, as shown in FIG. 2A. Although not particularly specified, each gate electrode 208 may include one or more work function layer(s) and a conductive material covering the work function layer(s).

Further, as shown in FIG. 2A and FIG. 2B, sidewalls of the gate structures 110 are covered by gate spacers 210. Moreover, as shown in FIG. 2A, each of the gate structures 110 may be laterally recessed at top and bottom sides of each wrapped channel structure 204 (except for the topmost one), and the associated lateral recess may be filled by inner spacers 212. While the gate spacers 210 cover most portions of the sidewalls of the gate structures 110, the inner spacers 212 may only cover portions of the gate structures 110 in between the wrapped channel structures 204. Sometimes, the portions of the gate structures 110 in lateral contact with the inner spacers 212 are referred to as “inner” gates.

As described with reference to FIG. 1, the active regions 100 are cut off at opposite sides of each gate structure 110, and source/drain terminals of the FETs are formed in the resulted breaks of the active regions 100. As shown in FIG. 2A, in some embodiments, the channel structures 204 of the active regions 100 are cut off by forming recesses extending into the semiconductor substrate 200, and epitaxial structures 214 as the source/drain terminals of the FETs are filled in these recesses. As a result, the epitaxial structures 214 are in lateral contact with the intersected channel structures 204, and may be laterally spaced apart from the gate structures 110 by the inner spacers 212 and the gate spacers 210. In some embodiments, the epitaxial structures 214 are formed to a height lower than top surfaces of the gate structures 110, and are respectively capped by a dielectric material 216 with a top surface leveled with the top surfaces of the gate structures 110.

Moreover, the dielectric material 216 may be further provided around the active regions 100 and the epitaxial structures 214. As shown in FIG. 2B, the dielectric material 216 is further disposed on the isolation structure 202 surrounding the active regions 100 (i.e., the channel structures 204), to fill up space around the active regions 100 and in between the gate structures 110. Although not particularly depicted, the dielectric material 216 may include an etching stop layer and a dielectric layer covering the etching stop layer.

As also shown in FIG. 2A and FIG. 2B, the channel structures 204 of the active regions 100 may be further cut off by the channel isolation structures 160 at the cell edges along the second direction Y. The channel isolation structures 160 may extend into the semiconductor substrate 200 through the dielectric material 216 and the isolation structure 202, and may have top surfaces substantially leveled with the top surfaces of the gate structures 110 and the dielectric material 216.

Moreover, as shown in FIG. 2C, the gate structures 110 may be cut off by the gate isolation structures 150 at the cell edges along the first direction X. The gate isolation structures 150 may be formed into the dielectric material 216 as shown in FIG. 2A and FIG. 2B, and may further extend through the isolation structure 202, such that the isolation structure 202 is not shown in the cross-sectional view of FIG. 2C. Alternatively, the gate isolation structures 150 may extend to a top surface of the isolation structure 202, and the gate isolation structure 202 lies in between the gate isolation structure 202 and the semiconductor substrate 200. In either case, although not specifically shown, the gate isolation structures 150 may be formed to a height substantially leveled with the top surfaces of the gate structures 110 and the dielectric material 216.

Referring to FIG. 2A, FIG. 2B and FIG. 2C, the signal lines 130 and the power rails 140 run over the afore-described ground level structures (i.e., including the channel structures 204, the gate structures 110, the epitaxial structures 214, the channel isolation structures 160 and the gate isolation structures 150). According to some embodiments, one or more interlayer dielectric layer(s) 218 lies between the ground level structures and conductive lines including the signal lines 130 and the power rails 140.

As shown in FIG. 2B, to establish connection between the gate structures 110 and the corresponding signal lines 130, the conductive vias 110V may be formed through the dielectric layer(s) 218, and connect the gate structures 110 to the overlying signal lines 130. Bottom ends of the conductive vias 110V may be in contact with the top surfaces of the gate structures 110, and top ends of the conductive vias 110V may be in contact with the corresponding signal lines 130.

On the other hand, referring to FIG. 2A and FIG. 2C, the epitaxial structures 214 are connected to the corresponding signal lines 130 and power rails 140 through the contact patterns 120 (including the contact patterns 120a, 120b) and conductive vias 120V (including the conductive vias 120Va, 120Vb). As shown in FIG. 2A, the contact patterns 120 are formed through portions of the dielectric material 216 above the epitaxial structures 214, and may further extend into the epitaxial structures 214. As shown in FIG. 2B, the contact patterns 120 may also laterally extend in portions of the dielectric material 216 around the active regions 100, and may overlap the isolation structure 202. Further, as shown in FIG. 2C, some of the contact patterns 120 (i.e., the contact patterns 120b) may each laterally extend through a shallow portion of one of the gate isolation structures 150. In some embodiments, top ends of the contact patterns 120 are substantially leveled with the top surfaces of the gate structures 110 and the dielectric material 216.

In some embodiments, each of the contact patterns 120 is laterally surrounded by a sidewall spacer 220 formed of an insulating material. The sidewall spacers 220 extend along sidewalls of the contact patterns 120 from the top ends of the contact patterns 120, but may not extend to bottom ends of the contact patterns 120. That is, the sidewall spacers 220 may not laterally surround bottom portions of the contact patterns 120, and the contact patterns 120 may extend deeper than the sidewall spacers 220. In this way, the sidewall spacers 220 would not block the contact patterns 120 from contacting the epitaxial structures 214.

As the contact patterns 120 are formed to a height lower than the signal lines 130 and the power rails 140, the conductive vias 120V are disposed on the contact patterns 120, and pick up the contact patterns 120 to the signal lines 130 and the power rails 140. Referring to FIG. 2A and FIG. 2C, the conductive vias 120V are formed through the interlayer dielectric layer(s) 218, and landed on the contact patterns 120. Top ends of the conductive vias 120V may be in contact with bottom surfaces of the corresponding signal lines 130 and power rails 140.

As described with reference to FIG. 1, the contact patterns 120b as source-side contacts may respectively have the first section 120b1 crossings the corresponding active region 100 and having the shorter width Wb1, and have the second section 120b2 overlapping the corresponding power rail 140 and having the greater width Wb2. On the other hand, the contact patterns 120a as drain-side contacts may respectively have the fixed width Wa along its length. The fixed width Wa is shorter than the width Wb2, and may be greater than the width 1. FIG. 2A and FIG. 2B respectively show one of the contact patterns 120a and the first section 120b1 of one of the contact patterns 120b, and FIG. 2C shows the second section 120b2 of one of the contact patterns 120b.

Due to etching behavior, the contact pattern 120 (or a section of the contact pattern 120) may have a smaller depth if it is formed with a shorter width, and have a greater depth if it is formed with a greater width. Therefore, a depth Db1 of the first section 120b1 of each contact pattern 120b (with the shorter width Wb1) as shown in FIG. 2A and FIG. 2B may be smaller than a depth Db2 of the second section 120b2 of each contact pattern 120b (with the greater width Wb2) as shown in FIG. 2C. Also, a depth Da of each contact pattern 120a (with the fixed width Wa) as shown in FIG. 2A and FIG. 2B may be smaller than the depth Db2 of the second section 120b2 of each contact pattern 120b as shown in FIG. 2C. In those embodiments where the width Wb1 of the first section 120b1 of each contact pattern 120b is shorter than the fixed width Wa of each contact pattern 120a, the depth Db1 of the first section 120b1 of each contact pattern 120b may be smaller than the depth Da of each contact pattern 120a.

As each contact pattern 120a and the first section 120b1 of each contact pattern 120b crossing the corresponding active regions 100 are respectively limited in terms of depth, they may be prevented from extending deeper than top ends of the inner spacers 212, and may not be laterally overlapped with the “inner gate” as portions of the gate structures 110 in lateral contact with the inner spacers 212. During manufacturing, it is rather difficult to control thickness of the inner spacers 212. The inner spacers 212 may not be able to properly isolate the “inner gates” from surrounding conductive components if they are formed very thin. In such case, undesired leakage paths from the inner gates to the contact patterns 120a and the first section 120b1 of each contact pattern 120b may be accidentally established, if the contact patterns 120a and the first section 120b1 of each contact pattern 120b are formed deeper than the top ends of the inner spacers 212. Therefore, by limiting depth of the contact patterns 120a and the first section 120b1 of each contact pattern 120b, undesired leakage from the inner gates to the contact patterns 120a and the first section 120b1 of each contact pattern 120b can be effectively avoided.

In those embodiments where the contact patterns 120a, 120b connected to P-type FETs are formed with widths Wb1, Wa shorter than widths Wa, Wb1 of the contact patterns 120a, 120b connected to N-type FETs, the contact patterns 120a, 120b connected to the P-type FETs may have smaller depths D1, D3 than the depths D1, D3 of the contact patterns 120a, 120b connected to the N-type FETs, and loss of the epitaxial structures 214 as the source/drain terminals of the P-type FETs in corresponding to formation of the overlying contact patterns 120a, 120b can be particularly reduced.

Further, as described with reference to FIG. 1, the conductive vias 120Vb each landed on the wider second section 120b2 of one of the contact patterns 120b is allowed to be formed with a greater width (i.e., the width W_{Vb}), to enhance interfacial conductivity between the conductive vias 120Vb and the contact patterns 120b. Since the width Wb2 of the second section 120b2 of each contact pattern 120b is greater than the fixed width Wa of the contact patterns 120a, the width W_{Vb} of each conductive via 120Vb (landed on the second section 120b2 of one of the contact patterns 120b) shown in FIG. 2C may be greater than the width W_{Va} of each conductive via 120Va (landed on one of the contact patterns 120a) as shown in FIG. 2A.

As above, preventing the leakage between the gate structures 110 and the source-side contact patterns 120b and reducing resistance from the source-side contact patterns 120b to the overlying power rails 140 can be realized at the same time by forming the source-side contact patterns 120b with multi-sectional design. It should be appreciated that the contact patterns 120b are depicted according to original layout design. Due to aggressive scaling, the manufactured contact patterns 120b may be slightly distorted from originally designed patterns.

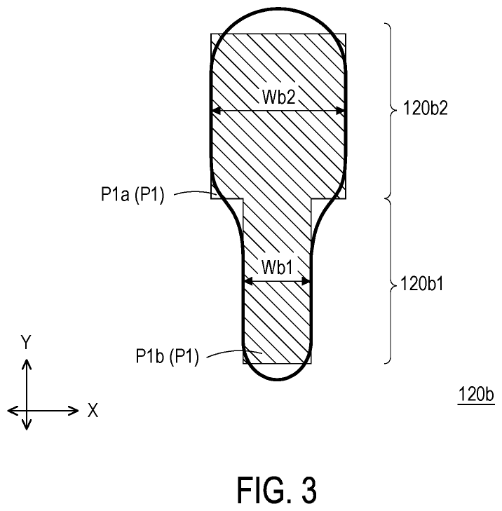

FIG. 3 is a schematic plan view illustrating an originally designed pattern P1 and a manufactured pattern P2 of one of the contact patterns 120b, according to some embodiments of the present disclosure.

Referring to FIG. 3, the originally designed pattern P1 of each contact pattern 120b may include a rectangular sub-pattern P1a as the first section 120b1, and include another rectangular sub-pattern P1b as the second section 120b2. That is, the originally designed pattern P1 has square edges along its contour. However, due to possible inaccuracy of photolithography and etching during manufacturing, the square edges may be rounded, as presented by the manufactured pattern P2. Nevertheless, the manufactured contact pattern 120b still has the first section 120b1 with a shorter width (i.e., the width Wb1) and the second section 120b2 with a greater width (i.e., the width Wb2), for preventing the afore-described gate leakage while maintaining or even reducing resistance from the contact patterns 120b to the power rails 140. Conceivably, although not particularly depicted, other patterns (which may include, for example, the contact patterns 120a and the conductive vias 110V, 120V) may also be distorted from original design in a similar way.

Moreover, further variations can be applied to the contact patterns 120b as well as the contact patterns 120a, according to some alternative embodiments of the present disclosure.

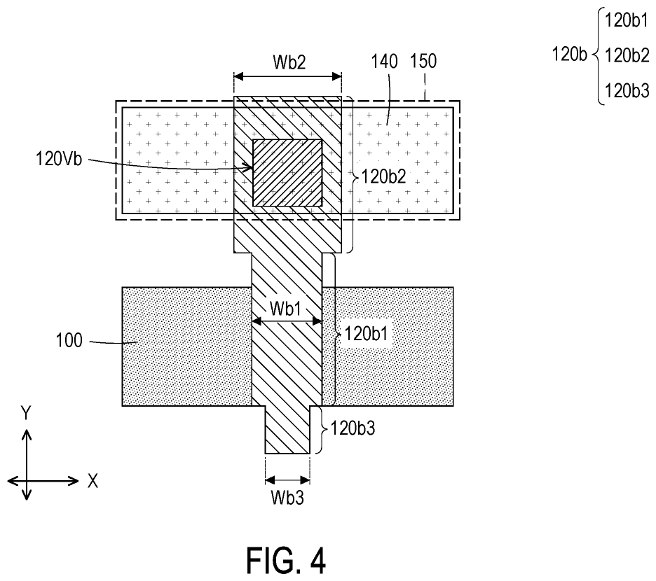

FIG. 4 is a schematic plan view illustrating one of the contact patterns 120b, according to some embodiments of the present disclosure.

Referring to FIG. 4, in some embodiments, some of the contact patterns 120b (or all of the contact patterns 120b) may be respectively divided into three sections. The first section 120b1 extend across the underlying active region 100, to the second section 120b2 overlapped with the corresponding conductive via 120Vb and power rail 140. In addition, a third section 120b3 extends away from a side of the first section 120b1 opposite to the second section 120b2, and entirely or mostly overlap the isolation structure (not shown) around the active region 100. As described, the first section 120b1 is formed with the width Wb1, and the second section 120b2 is formed with the width Wb2 greater than the width Wb1. Further, the third section 120b3 is formed with a width Wb3 shorter than the width Wb1 and the width Wb2.

In these embodiments, the width Wb3 of the third section 120b3 in each of these contact patterns 120b may be shorter than the width Wa of each contact pattern 120a (as shown in FIG. 1). Alternatively, the width Wb3 may be substantially identical with the width Wa, or greater than the width Wa.

Furthermore, the third section 120b3 in each of these contact patterns 120b may be formed with rounded edges, as similar to the first and second sections 120b1, 120b2 described with reference to FIG. 3.

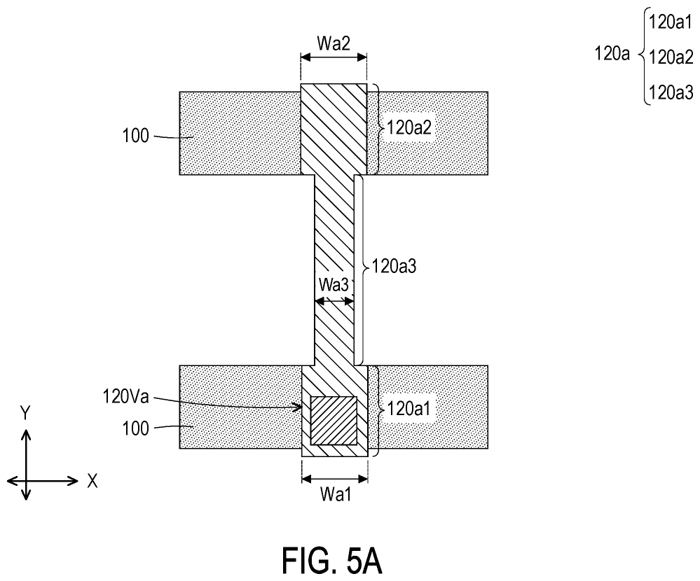

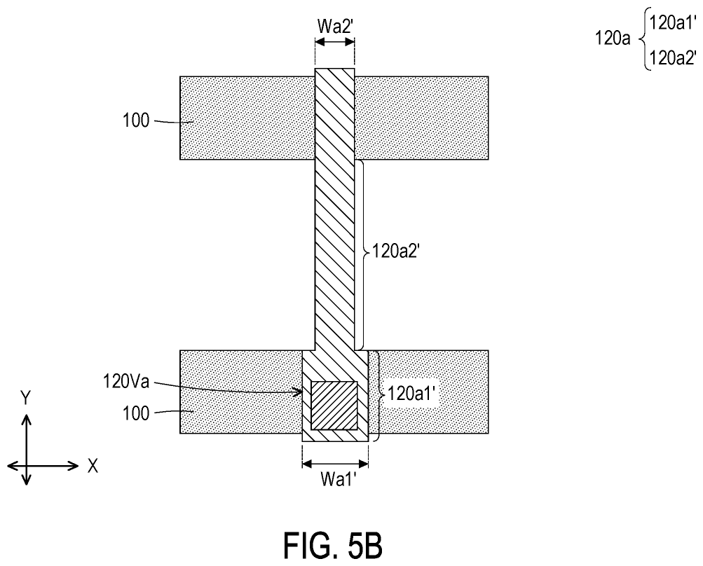

FIG. 5A and FIG. 5B are schematic plan views respectively illustrating one of the contact patterns 120a, according to some embodiments of the present disclosure.

According to the embodiments shown in FIG. 5A, some of (or all of) the contact patterns 120a respectively have multiple sections with different widths, rather than having a fixed width along length direction as described with reference to FIG. 1. As shown in FIG. 5A, each of these contact patterns 120a may include first and second sections 120a1, 120a2 crossing the active regions 100 and having widths Wa1, Wa2, respectively. In addition, each of these contact patterns 120a may also include a third section 120a3 extending between the first and second sections 120a1, 120a2 over the isolation structure (not shown) around the active regions 100, and having a width Wa3. The conductive vias 120Va for picking up these contact patterns 120a may be respectively formed on the first section 120a1 or the second section 120a2 of one of these contact patterns 120a. To ensure sufficient landing area for these conductive vias 120Va, the first and second sections 120a1, 120a2 of these contact patterns 120a are formed with a greater width. On the other hand, without being landed by any conductive via, the third section 120a3 of each of these contact patterns 120a may be formed with a shorter width. That is, the widths Wa1, Wa2 are greater than the width Wa3. In certain cases, the widths Wa1, Wa2 are substantially identical, and greater than the width Wa3. Although not particularly shown, the widths Wa1, Wa2, Wa3 are respectively shorter than the width Wb2 of the second section 120b2 in each contact pattern 120b, and may be each greater than, equal to or shorter than the width Wb1 of the first section 120b1 in each contact pattern 120b.

Referring to the embodiments shown in FIG. 5B, some of (or all of) the contact patterns 120a have two sections with different widths. Specifically, a first section 120a1′ in each of these contact patterns 120a extends across one of the active regions 100, and is landed with one of the conductive vias 120Va. In addition, a second section 120a2′ in each of these contact patterns 120a extends away from the first section 120a1′ to cross another one of the active regions 100 and overlie the isolation structure (not shown) between the active regions 100, but is not landed with any conductive via. The first section 120a1′ is formed with a larger width Wa1′, for ensuring sufficient landing area for the corresponding conductive via 120Va. On the other hand, without being landed by any conductive via, the second section 120a2′ may be formed with a shorter width Wa2′. That is, the width Wa1′ is greater than the width Wa2′. Although not particularly shown, the widths Wa1′, Wa2′ are respectively shorter than the width Wb2 of the second section 120b2 in each contact pattern 120b, and may be each greater than, equal to or shorter than the width Wb1 of the first section 120b1 in each contact pattern 120b.

It should be appreciated that the contact patterns 120a shown in FIG. 5A and FIG. 5B are originally designed patterns having square edges along their contours, and these square edges may be rounded upon manufacturing, as described with reference to FIG. 3.

According to various embodiments described above, the contact patterns 120a, 120b and the power rails 140 are formed over the FETs at a front side of the semiconductor substrate 200, as shown in FIG. 2A to FIG. 2C. However, in some further embodiments, the contact patterns 120a, 120b can be implemented by backside contact patterns formed below the FETs. Specifically, in some cases, the backside contact patterns implementing the contact patterns 120a, 120b may extend below the FETs, and are connected to bottom sides of the epitaxial structures 214 by through vias extending through the semiconductor substrate 200. Alternatively, the semiconductor substrate 200 may be entirely removed, and the through vias landed on the bottom sides of the epitaxial structures 214 may penetrate through an insulating material filled in the space previously occupied by the semiconductor substrate 200.

In addition, the power rails 140 and some of the signal lines 130 may run further below the FETs, and are connected to the contact patterns 120a, 120b by backside conductive vias, which are similar to the conductive vias 120Va, 120Vb described above, except for being disposed below the FETs. As an example, the contact patterns 120a, 120b and the conductive vias 120Va, 120Vb implemented by the backside contact patterns and the backside conductive vias are laid according to a layout design identical or similar to the layout design shown in FIG. 1.

Also, despite the FETs in various embodiments described above are implemented by GAA FETs, they can be alternatively implemented by fin-type FETs (FinFETs) or planar-type FETs, without changing the layout design. As compared to a GAA FET, a channel region of a FinFET is provided by one or more fin(s) defined on the semiconductor substrate 200, rather than a stack of the channel structures 204. On the other hand, a channel region of a planar-type FET is provided by a doped region formed inside the semiconductor substrate 200.

Moreover, there may be multiple integrated circuits in a single semiconductor chip. The contact patterns 120b (either implemented by frontside contact patterns or backside contact patterns) in some of the integrated circuits may be applied with the multi-sectional design described above, while the contact patterns 120b (either implemented by frontside contact patterns or backside contact patterns) in others of the integrated circuits may not be applied with the multi-sectional design.

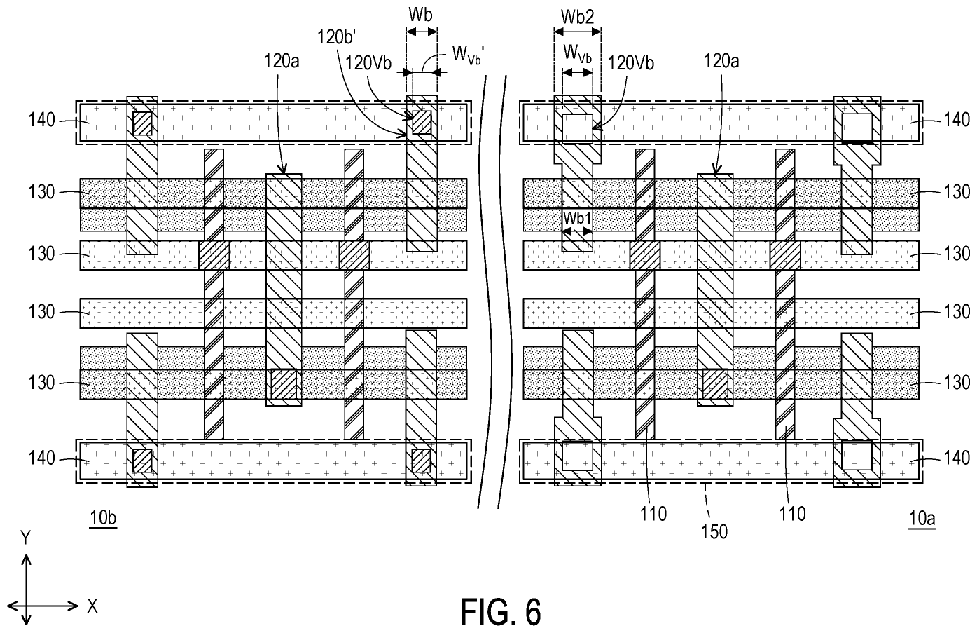

FIG. 6 is a schematic plan view illustrating a semiconductor chip according to some embodiments of the present disclosure.

Referring to FIG. 6, the semiconductor chip may include a first integrated circuit 10a implemented by the integrated circuit 10 described above and a second integrated circuit 10b slightly difference from the first integrated circuit 10a. Specifically, the first integrated circuit 10a has a contact pattern pitch (or referred to as contact poly pitch (CPP) greater than a contact pattern pitch of the second integrated circuit 10b. In addition, the contact patterns 120b in the first integrated circuit 10a may be applied with the multi-sectional design, while contact patterns 120b′ (connected to the power rails 140) in second integrated circuit 10b may be formed with a fixed width Wb along length direction. As a result, the width Wb2 of each contact pattern 120b in the first integrated circuit 10a is greater than the fixed width Wb of each contact pattern 120b′ in the second integrated circuit 10b. Accordingly, the width W_{Vb} (and hence the footprint area) of each conductive via 120Vb landing on one of the contact patterns 120b in the first integrated circuit 10a may be larger than a width W_{Vb}′ (and hence the footprint area) for each conductive via 120Vb landing on one of the contact patterns 120b′ in the second integrated circuit 10b.

Conceivably, the contact patterns 120b′ can have rounded edges, as similar to the contact patterns 120b described with reference to FIG. 3. Also, the variations to the contact patterns 120a described with reference to FIG. 4, FIG. 5A and FIG. 5B can be applied to the contact patterns 120a connected to the signal lines 130 in the second integrated circuit 10b.

As above, a solution is provided for aggressively miniaturizing an integrated circuit without risking gate to source/drain leakage and raise of source/drain to power rail resistance. Specifically, in such integrated circuit, a source/drain contact pattern for connecting a source/drain terminal of a FET to a power rail is formed with multi-sectional design. A first section of the source/drain contact pattern crossing an active region providing channel regions for the FET has a shorter width, and a second section of the source/drain contact pattern overlapped with the power rail has a greater width. As the first section of the source/drain contact pattern laterally adjacent to a gate structure is formed with the shorter width, a proper spacing between the source/drain contact and the gate structure can be ensured, and leakage in between can be effectively prevented. On the other hand, as the second section of the source/drain contact pattern overlapped with the power rail is formed with the greater width, a promising landing area can be provided for a conductive via connecting the source/drain contact pattern to the power rail, and resistance from the source/drain contact pattern to the power rail can be reduced. Therefore, instead of sacrificing one to achieve the other, prevention of the gate to source/drain leakage and reduction of source/drain to power rail resistance can be pursued at the same time.

In an aspect of the present disclosure, an integrated circuit is provided. The integrated circuit comprises: an active region, defined on a substrate by a surrounding isolation structure; a gate structure, intersecting and covering the active region; a first source/drain contact pattern, intersecting the active region at a first side of the gate structure; and a second source/drain contact pattern, intersecting the active region at a second side of the gate structure, and having a first section crossing the active region and a second section extending away from the first section and overlapped with a power rail, and the first section has a first width shorter than a second width of the second section.

In another aspect of the present disclosure, an integrated circuit is provided. The integrated circuit comprises: at least one channel structure, defined on a substrate by a surrounding isolation structure, and extending along a first lateral direction; a gate structure, extending along a second lateral direction, to intersect and cover the at least one channel structure; first and second source/drain structures, in lateral contact with the at least one channel structure from opposite sides; a first source/drain contact pattern, overlapping the first source/drain structure, and extending along the second lateral direction; and a second source/drain contact pattern, overlapping the second source/drain structure, and extending along the second lateral direction to be overlapped with a power rail, wherein a first section of the second source/drain contact pattern overlapping the second source/drain structure has a first width, and a second section of the second source/drain contact pattern overlapped with the power rail has a second width greater than the first width.

In yet another aspect of the present disclosure, a semiconductor chip is provided. The semiconductor chip comprises: a first integrated circuit and a second integrated circuit, built on a substrate, and each comprising: an active region, defined at a front surface of the substrate; a gate structure, intersecting and covering the active region; a first source/drain contact pattern, intersecting the active region at a first side of the gate structure; and a second source/drain contact pattern, intersecting the active region at a second side of the gate structure, and extending to be overlapped with a power rail. The second source/drain contact pattern in the first integrated circuit has a first section crossing the corresponding active region and a second section extending away from the first section and overlapped with the corresponding power rail, and the first section is formed with a first width shorter than a second width of the second section. In addition, the second source/drain contact pattern in the second integrated circuit has a fixed width from one side to the other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
an active region, defined on a substrate by a surrounding isolation structure;
a gate structure, intersecting and covering the active region;
a first source/drain contact pattern, intersecting the active region at a first side of the gate structure; and
a second source/drain contact pattern, intersecting the active region at a second side of the gate structure, and having a first section crossing the active region and a second section extending away from the first section and overlapped with a power rail, wherein the first section has a first width shorter than a second width of the second section.

2. The integrated circuit according to claim 1, wherein a difference between the first width and the second width ranges from about 0.5 nm to about 10 nm.

3. The integrated circuit according to claim 1, wherein the second source/drain contact pattern further has a third section extending away from a side of the first section opposite to the second section and laterally protruded from the active region, and a third width of the third section is shorter than the first width of the first section and the second width of the second section.

4. The integrated circuit according to claim 1, wherein the second source/drain contact pattern tapers from side to side in a plan view.

5. The integrated circuit according to claim 1, wherein the first source/drain contact pattern is formed with a fixed width from one end to the other, and the fixed width is shorter than the second width of the second section in the second source/drain contact pattern.

6. The integrated circuit according to claim 5, wherein a first conductive via standing on the first source/drain contact pattern is formed with a footprint area smaller than a footprint area of a second conductive via disposed on the second section of the second source/drain contact pattern.

7. The integrated circuit according to claim 1, wherein the first source/drain contact pattern has a first section crossing the active region and a second section overlapping the isolation structure and narrower than the first section of the first source/drain contact pattern.

8. The integrated circuit according to claim 7, wherein the first source/drain contact pattern further has a third section extending away from the second section of the first source/drain contact pattern and crossing another active region, wherein the second section of the first source/drain contact pattern is narrower than the first and third sections of the first source/drain contact pattern.

9. The integrated circuit according to claim 1, wherein the first source/drain contact pattern has a first section crossing the active region and overlapping the isolation structure as well as a second section crossing another active region, and the second section of the first source/drain contact pattern is formed wider than the first section of the first source/drain contact pattern.

10. An integrated circuit, comprising:
at least one channel structure, defined on a substrate by a surrounding isolation structure, and extending along a first lateral direction;
a gate structure, extending along a second lateral direction, to intersect and cover the at least one channel structure;
first and second source/drain structures, in lateral contact with the at least one channel structure from opposite sides;
a first source/drain contact pattern, overlapping the first source/drain structure, and extending along the second lateral direction; and
a second source/drain contact pattern, overlapping the second source/drain structure, and extending along the second lateral direction to be overlapped with a power rail, wherein a first section of the second source/drain contact pattern overlapping the second source/drain structure has a first width, and a second section of the second source/drain contact pattern overlapped with the power rail has a second width greater than the first width.

11. The integrated circuit according to claim 10, wherein the first and second source/drain contact patterns as well as the power rail are formed over the active region as well as the first and second source/drain structures at a front side of the substrate, the first source/drain contact pattern is formed into the first source/drain structure from above, and the first section of the second source/drain contact pattern is formed into the second source/drain structure from above.

12. The integrated circuit according to claim 10, wherein the first and second source/drain contact patterns are each laterally surrounded by a sidewall spacer.

13. The integrated circuit according to claim 12, wherein the first and second source/drain contact patterns are formed deeper than the surrounding sidewall spacers.

14. The integrated circuit according to claim 10, wherein the at least one channel structure comprises a stack of channel structures vertically separated from one another and each wrapped all around by the gate structure, and the gate structure is spaced apart from the first and second source/drain structure via inner spacers disposed between the channel structures.

15. The integrated circuit according to claim 14, wherein a bottom end of each of the first and second source/drain contact patterns is substantially leveled with or higher than a topmost end of the inner spacers.

16. The integrated circuit according to claim 10, wherein the first and second source/drain contact patterns as well as the power rail are disposed at a back side of the substrate, while the at least one channel structure, the gate structure and the first and second source/drain structures are formed at a front side of the substrate.

17. A semiconductor chip, comprising:
a first integrated circuit and a second integrated circuit, built on a substrate, and each comprising:
an active region, defined at a front surface of the substrate;
a gate structure, intersecting and covering the active region;
a first source/drain contact pattern, intersecting the active region at a first side of the gate structure; and
a second source/drain contact pattern, intersecting the active region at a second side of the gate structure, and extending to be overlapped with a power rail,
wherein the second source/drain contact pattern in the first integrated circuit has a first section crossing the corresponding active region and a second section extending away from the first section and overlapped with the corresponding power rail, and the first section is formed with a first width shorter than a second width of the second section,
wherein the second source/drain contact pattern in the second integrated circuit has a fixed width from one side to the other.

18. The semiconductor chip according to claim 17, wherein the second source/drain contact pattern is a source/drain contact of a P-type field effect transistor.

19. The semiconductor chip according to claim 17, wherein the first integrated circuit is designed with a contact pattern pitch greater than a contact pattern pitch of the second integrated circuit.

20. The semiconductor chip according to claim 17, wherein a field effect transistor (FET) defined at an intersection of the active region and the gate structure in each of the first and second integrated circuits is a gate-all-around FET, a fin-type FET or a planar-type FET.
